(19) United States
(12) Patent Application Publication
(10) Pub. No.: US 2011/0315214 A1
(43) Pub. Date: Dec. 29, 2011

(54) TRANSPARENT ELECTRICALLY CONDUCTIVE SUBSTRATE CARRYING THEREON A SURFACE ELECTRODE, A MANUFACTURING METHOD THEREFOR, A THIN-FILM SOLAR CELL AND A MANUFACTURING METHOD THEREFOR

(75) Inventors: Yasunori Yamanobe, Tokyo (JP); Fumihiko Matsumura, Tokyo (JP)

(73) Assignee: SUMITOMO METAL MINING CO., LTD., Tokyo (JP)

(21) Appl. No.: 13/167,505

(22) Filed: Jun. 23, 2011

(30) Foreign Application Priority Data
Jun. 28, 2010 (JP) P2010-146335

(51) Int. Cl. H01L 31/0224; B05D 5/12; C23C 14/04; H05K 1/09; H01L 31/18

(52) U.S. Cl. 136/256; 174/257; 438/71; 427/75; 427/526; 257/E31.126

(57) ABSTRACT

A transparent electrically conductive substrate having a high photovoltaic conversion efficiency surface electrode, and a method for its manufacture, are disclosed. A thin-film solar cell and a method for its manufacture are also disclosed. An indium oxide based amorphous transparent electrically conductive film is formed on the substrate as an underlying film 21 and a zinc oxide based crystalline transparent electrically conductive film is formed on the so formed amorphous transparent electrically conductive film to form a surface electrode 2 of an optimum uneven surface structure. As a consequence, the surface electrode 2 having a high light confining effect may be provided and a thin-film solar cell 10 may be provided which exhibits higher photovoltaic conversion efficiency (FIG. 1)

### BACKGROUND OF THE INVENTION

1. Field of the Invention

This invention relates to a transparent electrically conductive substrate carrying thereon a surface electrode, in which the transparent electrically conductive substrate is composed of a transparent electrically conductive film, and a method for manufacturing the substrate. This invention also relates to a thin-film solar cell manufactured using the transparent electrically conductive substrate carrying thereon a surface electrode, and a method for manufacturing the solar cell.

2. Description of Related Technology

In a thin-film solar cell that generates electricity as light is allowed to fall thereon at a light-transmitting substrate, such as a glass substrate, a transparent electrically conductive glass substrate carrying thereon an incident light side electrode is used. This incident light side electrode is referred to herein as a ‘surface electrode’. The surface electrode is formed by one or a plurality of transparent electrically conductive films of tin oxide, zinc oxide or indium oxide. If the surface electrode is formed by the multiple films, these are formed as layers stacked together. In the thin-film solar cell, a crystalline silicon thin film, such as polycrystalline silicon or a crystallite silicon thin film, or an amorphous silicon thin film, is used. Researches and developments of thin-film solar cells are now going on energetically. The goal of these researches and developments is to achieve low cost and high performance in combination mainly by forming a silicon thin film of satisfactory quality on an inexpensive substrate by a low temperature process.

As one of the above mentioned thin-film solar cells, there has been known such a cell in which a surface electrode, formed of a transparent electrically conductive film, a semiconductor layer with a photovoltaic conversion effect and a backside electrode, are sequentially layered on a light transmitting substrate. The semiconductor layer with a photovoltaic conversion effect is made up of a p-type semiconductor layer, an i-type semiconductor layer and an n-type semiconductor layer, stacked up sequentially, and the backside electrode includes a light reflective metal electrode. In this thin-film solar cell, the process of photovoltaic conversion occurs mainly within the i-type semiconductor layer, such that, if the i-type semiconductor layer is of a thin thickness, light in the long wavelength range, with a small light absorption coefficient, may not be absorbed sufficiently Viz., the value of photovoltaic conversion is intrinsically limited by the film thickness of the i-type semiconductor layer. It is desirable to more effectively exploit the light incident on the semiconductor layer with the photovoltaic conversion effect inclusive of the i-type semiconductor layer. With this in view, the surface electrode on the light incident side is provided with an uneven surface structure, whereby light is scattered into the semiconductor layer with the photovoltaic conversion effect. Further, the light reflected is randomly reflected by the backside electrode.

In such thin-film solar cell, the uneven surface structure of the light incident side surface electrode is routinely formed by thermal decomposition of a feedstock gas by a thermal CVD method for forming a thin film of fluoride-doped tin oxide on a glass substrate. See Patent document 1, for example.

However, the tin oxide film, having the uneven surface structure, is expensive since it is in need of a high temperature process with a temperature exceeding 500° C. On the other hand, the film has a high specific resistance. Thus, if the film thickness is increased, the light transmission becomes lower, thus deteriorating the photovoltaic conversion efficiency.

In another method proposed, a film of zinc oxide doped with Al (AZO film) or a film of zinc oxide doped with Ga (GZO film) is formed by sputtering on an underlying electrode formed by a film of tin oxide or a film of indium oxide doped with tin (ITO film). The zinc oxide film, susceptible to etching, is then etched to faun a surface electrode presenting an uneven surface structure. See Patent Document 2 for example. In still another method proposed, a film of zinc oxide doped with Al and Ga (GAZO film), not susceptible to arcing or particle generation during film forming, is formed by sputtering on an underlying electrode of a film of indium oxide doped with Ti having high light transmission performance for the near-infrared range light (ITiO film). The zinc oxide film is etched in the same way as in Patent Document 2 to form a surface electrode having an uneven surface structure. See Patent Document 3 for example.

### PATENT DOCUMENTS OF THE RELATED ART

### Patent Document

[Patent Document 1] Japanese Laid-Open Patent Publication Hei2-503615
[Patent Document 2] Japanese Laid-Open Patent Publication 2000-294812
[Patent Document 3] Japanese Laid-Open Patent Publication 2010-34232

### SUMMARY OF THE INVENTION

### Problem to be Solved by the Invention

However, in the known technique of etching the surface to produce an uneven surface structure, acutely pointed edges tend to be produced in the uneven film surface, such that only a non-optimum semiconductor layer with a photovoltaic conversion effect may be formed. As a result, the desired high photovoltaic conversion efficiency may not be obtained. In addition, if the post-etching rinsing is not sufficient, the semiconductor layer tends to suffer from defects. To prevent this from occurring, complex rinsing processes would be required, testifying to rather poor mass productivity of the known techniques.

The present invention has been proposed in light of the above depicted status of the art. It is an object of the present invention to provide a transparent electrically conductive substrate, carrying a surface electrode thereon, and a method for manufacturing the substrate, according to which the desired high photovoltaic conversion efficiency may be achieved. It is another object of the present invention to provide a thin-film solar cell and a method for manufacturing the cell.

### Means to Solve the Problem

The present inventors conducted perseverant researches, and have found that, when an indium oxide based amorphous transparent electrically conductive film is formed as an underlying layer, and a zinc oxide film is formed thereon, the growth of zinc oxide crystals is promoted more evidently than in the case of directly forming the zinc oxide film on the light-transmitting substrate.

In one aspect, the present invention provides a transparent electrically conductive substrate, carrying thereon a surface electrode, in which the transparent electrically conductive substrate comprises an indium oxide based amorphous electrically conductive transparent film and a zinc oxide based crystalline transparent electrically conductive film, sequentially deposited on the transparent substrate to form an uneven surface structure of the surface electrode.

In another aspect, the present invention provides a method for manufacturing a transparent electrically conductive substrate, carrying thereon a surface electrode, in which the method comprises sequentially layering an indium oxide based amorphous electrically conductive film and a zinc oxide based crystalline transparent electrically conductive film on a light-transmitting substrate to form an uneven surface structure of the surface electrode.

In still another aspect, the present invention provides a thin-film solar cell in which a surface electrode, a semiconductor layer with a photovoltaic conversion effect and a backside electrode are sequentially formed on a light-transmitting substrate, in which the surface electrode is formed on the light-transmitting substrate and made up of an indium oxide based amorphous transparent electrically conductive film and a zinc oxide based crystalline transparent electrically conductive film layered together to present an uneven surface structure.

In yet another aspect, the present invention provides a method for manufacturing a thin-film solar cell in which a surface electrode, a semiconductor layer with a photovoltaic conversion effect and a backside electrode are sequentially formed on a light-transmitting substrate. The method comprises sequentially depositing, on the light-transmitting substrate, an indium oxide based amorphous transparent electrically conductive film and a zinc oxide based crystalline transparent electrically conductive film to form an uneven surface structure of the surface electrode.

### Effect of the Invention

According to the present invention, in which an indium oxide based amorphous transparent electrically conductive film is formed as an underlying film, and a zinc oxide based crystalline electrically conductive film is formed thereon, a surface electrode presenting an optimum uneven surface structure may be formed without using an etching technique. As a consequence, a surface electrode having a higher light confinement effect may be obtained to render it possible to manufacture a thin film solar cell with the higher photovoltaic conversion efficiency.

### BRIEF DESCRIPTION OF THE DRAWINGS

FIG. 1 is a cross-sectional view showing an example constitution of a thin film according to an embodiment of the present invention.

FIG. 2 is a graph showing crystallinity of an underlying film plotted against the substrate temperature.

FIG. 3 is a graph showing crystal orientation of the film with an uneven surface against the substrate temperature at the time of forming of the underlying film.

### BEST MODE FOR CARRYING OUT THE INVENTION

Referring to the drawings, a preferred embodiment of the present invention will now be described in the following sequence:

1. Constitution of a thin-film solar cell
2. Method for manufacturing a thin-film solar cell

### <1. Constitution of a Thin-Film Solar Cell>

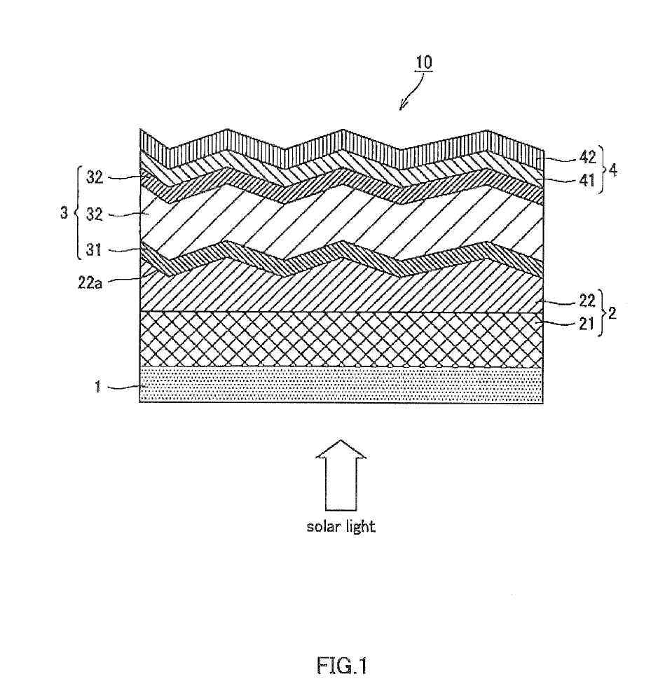

FIG. 1 is a cross-sectional view showing an example constitution of a thin-film solar cell 10 according to a preferred embodiment of the present invention. The thin-film solar cell has such a structure in which a surface electrode 2, a semiconductor layer with a photovoltaic conversion effect 3 and a backside electrode 4 are sequentially stacked on a light-transmitting glass substrate 1. Solar light to be photovoltaically converted falls on the thin-film solar cell 10 from the side the light-transmitting glass substrate 1, as indicated by arrow.

The light-transmitting glass substrate 1 preferably has a high light transmission in a wavelength range of from 350 to 1200 nm to render it possible to transmit the spectrum of the solar light. On the other hand, since the light-transmitting glass substrate 1 may be used outdoors, it is desirably stable electrically, chemically and physically. Examples of the light-transmitting glass substrate 1 may include substrates of soda lime silicate glass, borate glass, low alkali content glass, quartz glass and other sorts of glasses.

An alkali barrier film, such as silicon oxide film, may be deposited on the glass substrate. The reason of doing so is to prevent ion diffusion from the glass to a surface electrode of a transparent electrically conductive film deposited on the upper glass surface as well as to suppress the influences of the transparent electrically conductive film on the electrical characteristics brought about by difference in sorts or surface states of the glass substrates.

The surface electrode 2, formed on the light-transmitting glass substrate 1, is made up of an underlying film 21 and a film with an uneven surface 22 stacked up together. The underlying film 21 is an indium oxide based amorphous transparent electrically conductive film, whereas the film with an uneven surface 22 is a zinc oxide based crystalline transparent electrically conductive film. Similarly to the light-transmitting glass substrate 1, the surface electrode 2 preferably has a high transmission not less than 80 percent to light with a wavelength in a range of from 350 to 1200 nm. The surface electrode 2 desirably has a sheet resistance not higher than 10Ω/□. By ‘amorphous’ in the present specification is meant the property of a material exhibited in the X-ray analysis in which the diffraction peak intensity in the X-ray analysis of the material is not more than 10 percent of that of a corresponding crystalline material.

The underlying film 21 is the indium oxide based amorphous transparent electrically conductive film doped with at least one selected from the group of Ti, Sn and Ga. As such indium oxide based amorphous transparent electrically conductive film, an indium oxide film doped with Ti (ITiO film) may, for example, be used. The ITiO film has a high transmission to light in the near-infrared range. Also, the ITiO film may readily be rendered into an amorphous film, hi addition, the ITiO film may assist in the growth of the zinc oxide based crystal thereon.

As the indium oxide based amorphous transparent electrically conductive film, an indium oxide (ITGO) film, doped with Sn and Ga, may also be used. The ITGO film may be rendered into an amorphous film, while it may assist in the growth of the zinc oxide based crystal thereon.

As the indium oxide based amorphous transparent electrically conductive film, an indium oxide film doped with Ti and Sn (ITiTO film) may also be used. With the ITiTO film, the growth of the zinc oxide based crystal may be promoted more strongly than with the ITiO film.

The film thickness of the underlying film 21 is preferably 200 to 500 nm and more preferably from 300 to 400 nm. If the film thickness is less than 200 nm, the advantageous effect of an increased haze ratio, brought about by the underlying film 21, is appreciably reduced. On the other hand, if the film thickness exceeds 500 nm, light transmission is decreased to compromise the light confinement effect brought about by the increased haze ratio.

The film with an uneven surface 22, formed on the underlying film 21, is a zinc oxide based crystalline transparent electrically conductive film doped with at least one selected from the group of Al, Ga, B, In, F, Si, Ge, Ti, Zr and Hf. Among a variety of species of zinc oxide based films, thus obtained, a zinc oxide based film doped with both Al and Ga (GAZO film) is most preferred since it is hardly susceptible to arcing at the time of film forming by sputtering.

The film thickness of the crystalline transparent electrically conductive film is preferably 600 to 2000 nm and more preferably 800 to 1600 nm. If the film thickness is less than 600 nm, the degree of unevenness is not pronounced, with the haze ratio sometimes being lower than 10 percent. On the other hand, if the film thickness exceeds 2000 nm, light transmission is appreciably lowered.

By forming the indium oxide based amorphous transparent electrically conductive film, as the underlying film 21, and by forming the zinc oxide based crystalline transparent electrically conductive film thereon, as described above, the surface electrode 2 presenting a satisfactory uneven surface structure may be obtained. The degree of unevenness in the surface electrode 2, ultimately implemented, is preferably not lower than 10 percent in terms of the haze ratio which is an index for the surface roughness. On the other hand, the arithmetic average roughness (Ra) is preferably 30 to 100 nm. With the surface electrode of the uneven surface structure of the haze ratio and the arithmetic average roughness (Ra), the light confinement effect becomes higher, such that it is possible to improve the photovoltaic conversion efficiency of the thin-film solar cell 10.

The semiconductor layer with a photovoltaic conversion effect 3 is made up of a p-type semiconductor layer 31, an i-type semiconductor layer 32 and an n-type semiconductor layer 33, stacked together. Although the stacking order of the p-type semiconductor layer 31 and the n-type semiconductor layer 33 may be reversed, a p-type semiconductor layer is usually arranged in a solar cell on the light incident side of the cell.

The p-type semiconductor layer 31 may, for example, be a thin film of crystallite silicon doped with boron (B) as an impurity atom. It is also possible to use polycrystalline silicon, amorphous silicon, silicon carbide or silicon germanium in place of crystallite silicon. The impurity atom is not limited to B and may also be aluminum.

The i-type semiconductor layer 32 may be a thin film of non-doped crystallite silicon. It is also possible to use polysilicon, amorphous silicon, silicon carbide or silicon germanium in place of the crystallite silicon. It is further possible to use a silicon-based thin film material which is a weak p-type semiconductor or a weak n-type semiconductor that contains a trace amount of an impurity and that exhibits a sufficient photovoltaic conversion capability.

The n-type semiconductor layer 33 is formed of n-type crystallite silicon doped with phosphorus (P) as impurity atom. It is also possible to use polycrystalline silicon, amorphous silicon, silicon carbide or silicon germanium in place of crystallite silicon. The impurity atom is not limited to P and may also be nitrogen (N).

The backside electrode 4 is formed by the n-type semiconductor layer 33 on which a transparent electrically conductive oxide layer 41 and a light reflective metal electrode 42 are deposited in this order.

The transparent electrically conductive oxide layer 41 may not be necessary but may play the role of elevating the adhesion performance between the n-type semiconductor layer 33 and the light reflective metal electrode 42. The transparent electrically conductive oxide layer thus has the function to elevate the reflection efficiency of the light reflective metal electrode 42 as well as to protect the n-type semiconductor layer 33 from undergoing chemical changes.

The transparent electrically conductive oxide layer 41 is formed by at least one selected from the group of a zinc oxide film, an indium oxide film and a tin oxide film. If the transparent electrically conductive oxide layer is the zinc oxide film, it may preferably be doped with at least one out of Al and Ga, whereas, if the transparent electrically conductive oxide layer is the indium oxide film, it may preferably be doped with at least one out of Sn, Ti, W, Ce, Ga and MO. Doing so enhances the electrical conductivity. The specific resistance of the transparent electrically conductive oxide layer 41, neighboring to the n-type semiconductor layer 33, is preferably 1.5×10⁻³ Ωcm or less.

In the above mentioned constitution of the thin-film solar cell 10, the surface electrode 2 of an optimum uneven surface structure may be obtained, as a result of which the light confinement effect may be improved to accomplish a high photovoltaic conversion efficiency.

The above described constitution of the thin-film solar cell is only for illustration. For example, the surface electrode may be in two or more layers. That is, a film with an uneven surface 22, a zinc oxide based crystalline transparent electrically conductive film, may initially be formed on the underlying film 21, an indium oxide based amorphous transparent electrically conductive film. Another indium oxide based amorphous transparent electrically conductive film and another zinc oxide based crystalline transparent electrically conductive film may then be stacked in this order to provide a four-layered structure of the surface electrode. In this four-layered structure of the surface electrode, it becomes possible to vary the crystal grain size of the second and fourth layers of the zinc oxide films by varying the degree of amorphousness of the first and third layers of the indium oxide layers. This may yield a film with an uneven surface having two different periods, thus providing a surface electrode of a high haze ratio over a broad frequency band.

### <2. Method for Preparation of a Thin-Film Solar Cell>

A method for preparation of the above mentioned thin-film solar cell 10 will now be described. In the method for preparation in the present embodiment, a surface electrode 2, a semiconductor layer with a photovoltaic conversion effect 3 and a backside electrode 4 are deposited in this order on a light-transmitting glass substrate 1.

Initially, in forming the surface electrode 2, an underlying film 21, an amorphous transparent electrically conductive film of the indium oxide system, is formed on the light-transmitting glass substrate 1. More specifically, the light-transmitting glass substrate 1 is kept at a temperature of from ambient temperature to 50° C., and an amorphous transparent electrically conductive film is formed thereon by a sputtering method. The amorphous transparent electrically conductive film of the indium oxide system may be obtained even with the temperature of the light-transmitting glass substrate 1 lower than the ambient temperature. It is however necessary in such case to provide a mechanism of cooling the light-transmitting glass substrate 1 within a sputtering device, thus undesirably elevating the cost. If the temperature of the light-transmitting glass substrate 1 exceeds 50° C., it becomes difficult to produce the amorphous transparent electrically conductive film of the indium oxide system.

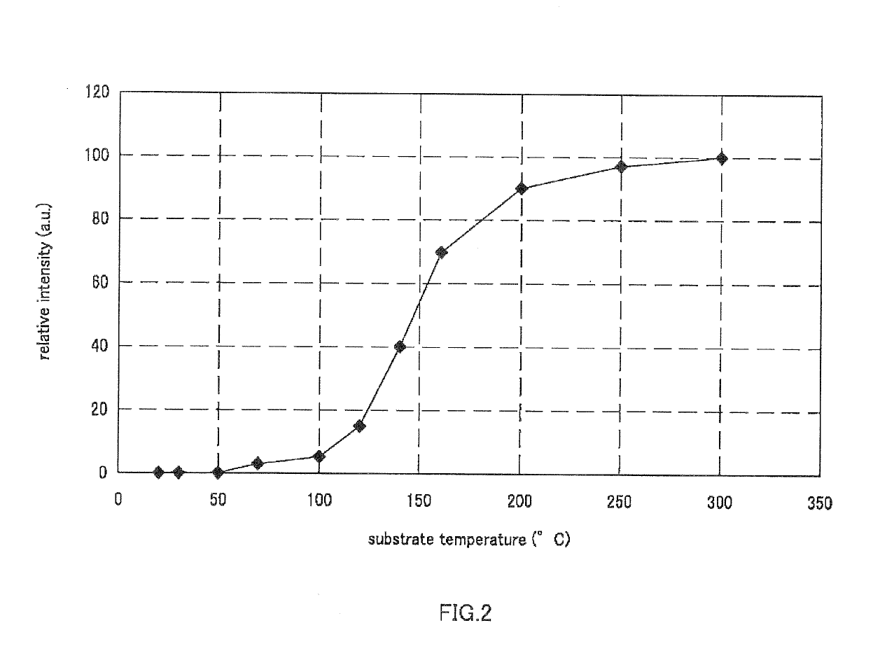

FIG. 2 depicts a graph showing crystallinity oldie underlying film with respect to the substrate temperature. A soda lime silicate glass substrate was used as the light-transmitting glass substrate 1, and an ITiO film, with the doped amount of titanium oxide being 1 mass weight percent, was formed thereon as the underlying film 21. A mixed gas of argon and oxygen (argon:oxygen=99:1) was introduced, and the ITiO film was deposited by the sputtering method to a film thickness of 200 nm. The crystallinity of the ITiO film was evaluated as the temperature of the soda lime silicate glass substrate was varied in a range of from 25° C. to 300° C. The crystallinity was evaluated in terms of a ratio of diffraction peak intensity of the (222) plane of an ITiO film formed on a soda lime silicate glass substrate kept at each of various preset silicate glass substrate temperatures to diffraction peak intensity of 100 percent of the (222) plane of the ITiO film formed as the soda lime silicate glass substrate was heated to 300°. The X-ray diffraction (XRD) method was used for measuring the diffraction peak intensity.

In the graph of FIG. 2, a film with the diffraction peak intensity ratio not more than 10% is an amorphous ITiO film. Hence, the substrate temperature is preferably not higher than 100° C. and more preferably in a range of from ambient temperature to 50° C. The same may be said in case of using an ITiTO film in place of the ITiO film; to obtain an amorphous film of the indium oxide system, it is necessary to keep the substrate temperature in a range of from ambient to 50° C. It is observed that, even if the substrate temperature is lower than the ambient, the film of the indium oxide system obtained is amorphous. This, however, is not desirable because it is necessary to provide a mechanism for cooling the light-transmitting glass substrate 1 within the sputtering device, thus undesirably raising the cost.

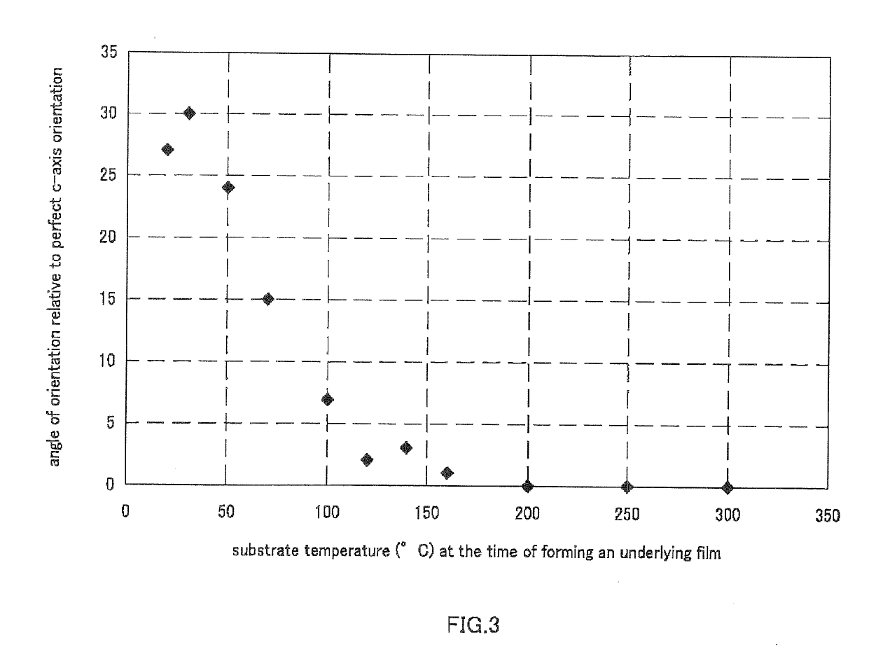

FIG. 3 is a graph showing crystal orientation of a film with an uneven surface structure against the substrate temperature at the time of depositing an underlying film. In the same way as in crystallinity evaluation, described above, a soda lime silicate glass substrate was used as the light-transmitting glass substrate 1, and an ITiO film, with the doped amount of titanium oxide being 1 mass weight percent, was formed thereon as underlying film 21. A mixed gas of argon and oxygen (argon:oxygen=99:1) was introduced and, as the temperature of the soda lime silicate glass substrate was varied in a range of from 25° C. to 300° C., an ITiO film was deposited by the sputtering method to a film thickness of 200 nm. On this ITiO film of the underlying film 21, a GAZO film was formed to a film thickness of 600 nm by the sputtering method, as the substrate temperature was kept at 300° C. A gas introduced was 100 percent argon gas and the sputtering power used was DC 400 W. The GAZO film was analyzed by X-ray diffraction and measurement was made of the angle of orientation (°) with respect to perfect c-axis orientation.

From the graph shown in FIG. 3, it is seen that the GAZO film, deposited on the ITiO film as the substrate temperature was kept at 50° C. or lower, exhibited crystalline orientation inclined 15 to 30° with respect to the c-axis. Viz., it may be seen that, by depositing the underlying film 21 with the substrate temperature in a range from ambient to 50° C., the film with an uneven surface 22, formed on the underlying film 21, presents an optimum uneven or crest-trough structure.

The film thickness of the underlying film 21 deposited is preferably 200 to 500 nm and more preferably 300 to 400 nm. If the film thickness is less than 200 nm, the advantageous effect of the increased haze ratio brought about by underlying film is appreciably reduced, whereas, if the film thickness exceeds 500 nm, light transmission decreases to cancel out the light confinement effect brought about by the increase in the haze ratio.

A crystalline transparent electrically conductive film of the zinc oxide system is then deposited as a film with an uneven surface 22 on the underlying film 21. The crystalline transparent electrically conductive film of the zinc oxide system is formed by the sputtering method as the substrate temperature is kept at 250° C. to 300° C. With the substrate temperature lower than 250° C., crystallization of zinc oxide is retarded in the course of deposition of the zinc oxide film, such that it becomes difficult to obtain a film with an uneven surface with the haze ratio exceeding 10 percent. On the other hand, the substrate temperature exceeding 300° C. deteriorates amorphousness of the underlying film 21, even though it is advantageous to crystallization of the zinc oxide film. It is because the underlying film 21 is deteriorated in amorphousness. Thus, the c-axis orientation of the zinc oxide film becomes more pronounced, with the film surface becoming more planar. It is thus difficult to obtain a film with an uneven surface with the haze ratio not less than 10 percent.

As discussed with reference to FIGS. 2 and 3, the formation of the uneven or crest-trough surface structure may be controlled by the degree of amorphousness of the amorphous transparent electrically conductive film, which is the underlying film 21. To enlarge the crystal grain size, a perfectly amorphous film is preferred. On the other hand, to reduce the crystal grain size, an amorphous film close to a crystallite film is preferred. Viz., to increase the crystal grain size at a substrate temperature ranging from ambient to 50° C., the substrate temperature is set to a lower temperature, whereas, to reduce the crystal grain size, the substrate temperature is set to a higher temperature to control the crystallinity of the underlying film 21. By so doing, it becomes possible to control the crystal grain size of the transparent electrically conductive film of the zinc oxide system deposited on the underlying film to control the crest-trough shape.

The degree of unevenness of the surface electrode 2, ultimately realized, is preferably not lower than 10 percent in terms of the haze ratio, an index indicating the surface unevenness. On the other hand, an arithmetic mean roughness (Ra) is preferably 30 to 100 nm. With the surface electrode having the uneven surface structure of the above mentioned haze ratio and the arithmetic mean roughness (Ra), a high light confinement effect may be obtained, thus enhancing the photovoltaic conversion efficiency of the thin film solar cell 10.

The film thickness of the film with an uneven surface 22 is preferably 600 to 2000 nm and more preferably 800 to 1600 mm. If the film thickness is less than 600 nm, the crests/troughs may fail to be pronounced and the film's haze ratio may sometimes be lower than 10 percent. If the film thickness exceeds 2000 nm, light transmission is lowered significantly.

The semiconductor layer with a photovoltaic conversion effect 3 is then formed on the surface electrode 2, using a plasma CVD (Chemical Vapor Deposition) method, in which the underlayer temperature is set to not higher than 400° C. The plasma CVD method may be a generally well-known parallel flat plate configuration RF plasma CVD or may also be a plasma CVD method that exploits a high frequency power supply with the frequency ranging from an RF band not higher than 150 MHz to a VHF range.

The semiconductor layer with a photovoltaic conversion effect 3 then is formed by stacking a p-type semiconductor layer 31, an i-type semiconductor layer 32 and an n-type semiconductor layer 33 in this order. Each of these semiconductor layers may be irradiated as necessary with pulsed laser light by way of laser annealing such as to control the crystallinity or the carrier concentration.

A backside electrode 4 then is formed on the semiconductor layer with a photovoltaic conversion effect 3. The backside electrode 4 is formed by sequentially forming a transparent electrically conductive oxide layer 41 and a light reflective metal electrode 42.

The transparent electrically conductive oxide layer 41, which may not always be necessary, raises the adhesion performance of the n-type semiconductor layer 33 and the light reflective metal electrode 42 to each other. Thus, it has the function of raising the reflection efficiency of the n-type semiconductor layer 33 with respect to the light reflective metal electrode 42 while protecting the n-type semiconductor layer 33 against chemical changes.

Preferably, the light reflective metal electrode 42 is formed by vacuum deposition or sputtering, and formed of a metal selected from the group consisting of Ag, Au, Al, Cu, Pt and an alloy containing one or more of these metals as alloying element(s). For example, the light reflective metal electrode is formed by vacuum deposition of highly light reflective Ag at a temperature of preferably 100 to 330° C. and more preferably 200 to 300° C.

With the above mentioned manufacturing method, a surface electrode presenting an optimum uneven surface may be formed without employing an etching technique. Thus, as a result, it becomes possible to provide a surface electrode having a high light confinement effect and hence a thin film solar cell with high photovoltaic conversion efficiency.

Moreover, the thin film solar cell may be manufactured by solely physical vapor deposition (PVD) or by chemical vapor deposition (CVD), and hence the manufacturing cost may be reduced.

If the surface electrode is to be of a four-layered structure, stacked together, the film with an uneven surface 22, a crystalline transparent electrically conductive film of the zinc oxide system, is first formed on the underlying film 21, an amorphous transparent electrically conductive film of the indium oxide system. Then, another amorphous transparent electrically conductive film of the indium oxide system and a crystalline transparent electrically conductive film of the zinc oxide system are formed thereon in this order. In the surface electrode of the four-layered structure, it is possible to vary the crystal grain size of the zinc oxide films of the second and fourth layers by changing the degree of amorphousness of the indium oxide films of the first and third layers. In this manner, a film with an uneven surface of two different periods may be obtained, thus providing a surface electrode presenting a high haze ratio over a broad wavelength range.

### EXAMPLES

The present invention will now be described with respect to several Examples, which are given only for illustration and not for restricting the invention.

### Example 1

Under the following conditions, a thin-film solar cell of the silicon system, having a structure shown in FIG. 1, was prepared.

### [Evaluation of Surface Electrode]

First of all, a soda lime silicate glass substrate was used as the light-transmitting glass substrate 1. An underlying film 21 and a film with an uneven surface 22 were formed in this order on the glass substrate as a surface electrode 2. An ITiO film, formed of indium oxide doped with 1 mass weight percent of titanium oxide, was used as the underlying film 21, and a GAZO film, formed of zinc oxide doped with 0.58 mass weight percent of gallium oxide and 0.32 mass weight percent of aluminum oxide, was used as the film with an uneven surface 22.

The temperature of the soda lime silicate glass substrate was set at 25° C. Using a mixed gas of argon and oxygen (argon:oxygen=99:1) as a gas to be introduced, the ITiO film was deposited on the substrate by a sputtering method to a film thickness of 200 nm. As the temperature of the soda lime silicate glass substrate was set at 300° C., a GAZO film was deposited to a film thickness of 600 nm, with the sputtering power of DC 400 W, using a 100 percent argon gas as the gas introduced. Table 1 shows manufacturing conditions for manufacturing the surface electrode.

Using a surface resistance meter Loresta AP (manufactured by Mitsubishi Chemical Corporation, MCP-T400 type), measurement was made of a sheet resistance of a surface electrode. Also, using a haze meter (manufactured by Murakami Color Research Laboratory, HR-200 type), measurement was made of a haze ratio of the surface electrode. Furthermore, using a surface roughness meter (manufactured by Tokyo Seimitsu Co. Ltd. Surfcom 1400A type), measurement was made of an arithmetic average roughness (Ra) of the surface electrode.

As a result, the sheet resistance value was found to be 9.1Ω/□, the haze ratio was found to be 15 percent and the arithmetic average roughness (Ra) was found to be 63 μm. FIG. 2 shows the results of measurement of the surface electrode.

### [Evaluation of Solar Cell]

By the plasma CVD method, a p-type crystallite silicon layer, doped with boron, as a p-type semiconductor layer 31, with a thickness of 10 nm, an i-type crystallite silicon layer 32, with a thickness of 3 μm, and an n-type crystallite silicon layer doped with phosphorus, with a film thickness of 15 nm, as a p-type semiconductor layer 33, were deposited in this order on the surface electrode to form a pin junction semiconductor layer with a photovoltaic conversion effect.

On this semiconductor layer with a photovoltaic conversion effect, the transparent electrically conductive oxide film 41 and the light reflective metal electrode 42 were deposited in this order to provide the backside electrode 4. As the transparent electrically conductive oxide film 41, a GAZO film formed of zinc oxide with a thickness of 70 nm, doped with 2.3 weight percent of gallium oxide and 12 weight percent of aluminum oxide, was used and, as the light reflective metal electrode 42, an Ag film with a thickness of 300 nm was used.

More specifically, the GAZO film was deposited by sputtering on the semiconductor layer with a photovoltaic conversion effect to a film thickness of 70 nm, and an Ag film was deposited thereon to a film thickness of 300 nm to form the backside electrode.

The thin-film solar cell, thus obtained, was irradiated with light with an air mass (AM) of 1.5, with a light volume of 100 mW/cm², to measure characteristics at 25° C. of the thin-film solar cell. As a result, the photovoltaic conversion efficiency was found to be 8.4 percent Table 2 shows measured values of the cell characteristics.

### Example 2

A surface electrode was formed in the same way as in Example 1 except setting the temperature of the soda lime silicate glass substrate in forming the ITiO film to 50° C., and measurement was made of characteristics of the surface electrode. As a result, the sheet resistance value was found to be 8.5Ω/□, the haze ratio was found to be 14 percent and the arithmetic average roughness (Ra) was found to be 60 nm. A thin-film solar cell was formed on the surface electrode in the same way as in Example 1 to measure the cell characteristics. The photovoltaic conversion efficiency was found to be 8.2 percent.

### Example 3

A surface electrode was formed in the same way as in Example 1 except setting the temperature of the soda lime silicate glass substrate in forming the GAZO film to 250° C., and measurement was made of its characteristics. As a result, the sheet resistance value was found to be 8.3Ω/□, the haze ratio was found to be 13 percent and the arithmetic average roughness (Ra) was found to be found to be 61 nm. A thin-film solar cell was formed on the surface electrode in the same way as in Example 1 to measure cell characteristics. The photovoltaic conversion efficiency was found to be 8.3 percent.

### Example 4

A surface electrode was formed in the same way as in Example 1 except setting the film thickness of the ITiO film to 300 nm, and measurement was made of characteristics of the surface electrode. As a result, the sheet resistance value was found to be 8.1Ω/□, the haze ratio was found to be 16 percent and the arithmetic average roughness (Ra) was found to be 64 nm. A thin-film solar cell was formed on the surface electrode in the same way as in Example 1 to measure its characteristics. The photovoltaic conversion efficiency was found to be 8.5 percent.

### Example 5

A surface electrode was formed in the same way as in Example 1 except setting the film thickness of the ITiO film to 400 nm, and measurement was made of its characteristics. As a result, the sheet resistance value was found to be 7.9Ω/□, the haze ratio was found to be 15 percent and the arithmetic average roughness (Ra) was found to be 64 nm. A thin-film solar cell was formed on the surface electrode in the same way as in Example 1 to measure its characteristics. The photovoltaic conversion efficiency was found to be 8.4 percent.

### Example 6

A surface electrode was formed in the same way as in Example 1 except setting the film thickness of the ITiO film to 500 nm, and measurement was made of its characteristics. As a result, the sheet resistance value was found to be 7.8Ω/□, the haze ratio was found to be 16 percent and the arithmetic average roughness (Ra) was found to be 65 nm. A thin-film solar cell was formed on the surface electrode in the same way as in Example 1 to measure its characteristics. The photovoltaic conversion efficiency was found to be 8.4 percent.

### Example 7

A surface electrode was formed in the same way as in Example 1 except setting the film thickness of the GAZO film to 800 nm, and measurement was made of its characteristics. As a result, the sheet resistance value was found to be 8.9Ω/□, the haze ratio was found to be 16 percent and the arithmetic average roughness (Ra) was found to be 65 nm. A thin-film solar cell was foamed on the surface electrode in the same way as in Example 1 to measure cell characteristics. The photovoltaic conversion efficiency was found to be 8.5 percent.

### Example 8

A surface electrode was formed in the same way as in Example 1 except setting the film thickness of the G&W film to 1600 nm, and measurement was made of its characteristics. As a result, the sheet resistance value was found to be 8.8Ω/□, the haze ratio was found to be 22 percent and the arithmetic average roughness (Ra) was found to be 66 nm. A thin-film solar cell was formed on the surface electrode in the same way as in Example 1 to measure cell characteristics. The photovoltaic conversion efficiency was found to be 8.5 percent.

### Example 9

A surface electrode was formed in the same way as in Example 1 except setting the film thickness of the GAZO film to 2000 nm, and measurement was made of its characteristics. As a result, the sheet resistance value was found to be 8.6Ω/□, the haze ratio was found to be 32 percent and the arithmetic average roughness (Ra) was found to be 68 nm. A thin-film solar cell was formed on the surface electrode in the same way as in Example 1 to measure cell characteristics. The photovoltaic conversion efficiency was found to be 8.4 percent.

### Example 10

A surface electrode was prepared in the same way as in Example except using an ITiTO film as the underlying film 21 to evaluate its characteristics. This ITiTO film was formed of indium oxide doped with 1 mass weight percent of titanium oxide and 0.01 mass weight percent of tin oxide. As a result, the sheet resistance value was found to be 8.9Ω/□, the haze ratio was found to be 17 percent and the arithmetic average roughness (Ra) was found to be 66 nm. A thin-film solar cell was formed on the surface electrode in the same way as in Example 1 to measure cell characteristics. The photovoltaic conversion efficiency was found to be 8.5 percent.

### Example 11

A surface electrode was prepared in the same way as in Example 1 except using an ITiTO film as the underlying film 21, and setting its film thickness to 300 nm, and evaluation was made of its characteristics. As a result, the sheet resistance value was found to be 8.7Ω/□, the haze ratio was found to be 19 percent and the arithmetic average roughness (Ra) was found to be 67 nm. A thin-film solar cell was formed on the surface electrode in the same way as in Example 1 to measure cell characteristics. The photovoltaic conversion efficiency was found to be 8.5 percent.

### Example 12

A surface electrode was prepared in the same way as in Example 1 except using the ITiTO film of Example 10 as the underlying film 21 and setting the film thickness of the ITiTO film at 400 nm, and measurement was made of its characteristics. As a result, the sheet resistance was found to be 8.5Ω/□, the haze ratio was found to be 19 percent and the arithmetic average roughness (Ra) was found to be 67 nm. A thin-film solar cell was formed on this surface electrode, in the same way as in Example 1, and measurement was made of its characteristics. As a result, the photovoltaic conversion efficiency was found to be 8.4 percent.

### Example 13

A surface electrode was prepared in the same way as in Example 1 except using the ITiTO film of Example 10 as the underlying film 21 and setting the film thickness of the ITiTO film at 400 nm and that of the GAZO film at 800 nm, and measurement was made of its characteristics. As a result, the sheet resistance was found to be 8.3Ω/□, the haze ratio was found to be 20 percent and the arithmetic average roughness (Ra) was found to be 70 nm. A thin-film solar cell was formed on this surface electrode, in the same way as in Example 1, and measurement was made of its characteristics. As a result, the photovoltaic conversion efficiency was found to be 8.5 percent.

### Example 14

A surface electrode was prepared in the same way as in Example 1 except using the ITiTO film of Example 10 as the underlying film 21, setting the film thickness of the ITiTO film at 400 nm and setting that of the GAZO film at 1600 nm, and measurement was made of its characteristics. As a result, the sheet resistance was found to be 8.2Ω/□, the haze ratio was found to be 31 percent and the arithmetic average roughness (Ra) was found to be 72 nm. A thin-film solar cell was formed on this surface electrode, in the same way as in Example 1, and measurement was made of its characteristics. As a result, the photovoltaic conversion efficiency was found to be 8.6 percent.

### Example 15

A surface electrode was prepared in the same way as in Example 1 except using the ITiTO film of Example 10 as the underlying film 21 and setting the film thickness of the ITiTO film at 400 nm and that of the GAZO film at 2000 nm, and measurement was made of its characteristics. As a result, the sheet resistance was found to be 8.0Ω/□, the haze ratio was found to be 34 percent and the arithmetic average roughness (Ra) was found to be 72 nm. A thin-film solar cell was formed on this surface electrode, in the same way as in Example 1, and measurement was made of its characteristics. As a result, the photovoltaic conversion efficiency was found to be 8.3 percent.

### Example 16

A surface electrode was formed in the same way as in Example 1, except using an ITGO film as the underlying film 21, and measurement was made of its characteristics. The ITGO film was formed of indium oxide doped with 10 mass weight percent of tin oxide and 3.4 mass weight percent of gallium oxide. As a result, the sheet resistance was found to be 8.8Ω/□, the haze ratio was found to be 18 percent and the arithmetic average roughness (Ra) was found to be 67 nm. A thin-film solar cell was formed on this surface electrode, in the same way as in Example 1, and measurement was made of its characteristics. As a result, the photovoltaic conversion efficiency was found to be 8.6 percent.

### Example 17

A surface electrode was prepared in the same way as in Example 1 except using the ITGO film of Example 10 as the underlying film 21 and setting the film thickness of the ITGO film at 300 nm, and measurement was made of its characteristics. As a result, the sheet resistance was found to be 8.2Ω/□, the haze ratio was found to be 18 percent and the arithmetic average roughness (Ra) was found to be 67 nm. A thin-film solar cell was formed on this surface electrode, in the same way as in Example 1, and measurement was made of its characteristics. As a result, the photovoltaic conversion efficiency was found to be 8.7 percent.

### Example 18

A surface electrode was prepared in the same way as in Example 1 except using the ITGO film of Example 16 as the underlying film 21 and setting the film thickness of the ITGO film at 400 nm, and measurement was made of its characteristics. As a result, the sheet resistance was found to be 7.8Ω/□, the haze ratio was found to be 19 percent and the arithmetic average roughness (Ra) was found to be 68 nm. A thin-film solar cell was formed on this surface electrode, in the same way as in Example 1, and measurement was made of its characteristics. As a result, the photovoltaic conversion efficiency was found to be 8.8 percent.

### Example 19

A surface electrode was prepared in the same way as in Example 1 except using the ITGO film of Example 16 as the underlying film 21 and setting the temperature of the soda lime silicate glass substrate at 250° C. at the time of forming the GAZO film, and measurement was made of its characteristics. As a result, the sheet resistance was found to be 9.0Ω/□, the haze ratio was found to be 14 percent and the arithmetic average roughness (Ra) was found to be 62 nm. A thin-film solar cell was formed on this surface electrode, in the same way as in Example 1, and measurement was made of its characteristics. As a result, the photovoltaic conversion efficiency was found to be 8.2 percent.

### Example 20

A surface electrode was prepared in the same way as in Example 1 except using the ITGO film of Example 16 as the underlying film 21 and setting the film thickness of the GAZO film at 2000 nm, and measurement was made of its characteristics. As a result, the sheet resistance was found to be 7.7Ω/□, the haze ratio was found to be 42 percent and the arithmetic average roughness (Ra) was found to be 73 nm. A thin-film solar cell was formed on this surface electrode, in the same way as in Example 1, and measurement was made of its characteristics. As a result, the photovoltaic conversion efficiency was found to be 8.8 percent.

### Comparative Example 1

A surface electrode was prepared in the same way as in Example 1 except setting the temperature of the soda lime silicate glass substrate in depositing the ITiO film at 70° C. As a result, the sheet resistance was found to be 8.3Ω/□, the haze ratio was found to be 9 percent and the arithmetic average roughness (Ra) was found to be 52 nm. A thin-film solar cell was formed on this surface electrode, in the same way as in Example 1, and measurement was made of its characteristics. As a result, the photovoltaic conversion efficiency was found to be 7.8 percent.

### Comparative Example 2

A surface electrode was prepared in the same way as in Example 1 except setting the temperature of the soda lime silicate glass substrate in depositing the ITiO film at 100° C. As a result, the sheet resistance was found to be 8.2Ω/□, the haze ratio was found to be 7 percent and the arithmetic average roughness (Ra) was found to be 50 nm. A thin-film solar cell was formed on this surface electrode, in the same way as in Example 1, and measurement was made of its characteristics. As a result, the photovoltaic conversion efficiency was found to be 7.7 percent.

### Comparative Example 3

A surface electrode was prepared in the same way as in Example 1 except setting the temperature of the soda lime silicate glass substrate in depositing the ITiO film at 120° C. As a result, the sheet resistance was found to be 8.3Ω/□, the haze ratio was found to be 7 percent and the arithmetic average roughness (Ra) was found to be 43 nm. A thin-film solar cell was formed on this surface electrode, in the same way as in Example 1, and measurement was made of its characteristics. As a result, the photovoltaic conversion efficiency was found to be 7.9 percent.

### Comparative Example 4

A surface electrode was prepared in the same way as in Example 1 except setting the temperature of the soda lime silicate glass substrate in depositing the ITiO film at 150° C. As a result, the sheet resistance was found to be 8.1Ω/□, the haze ratio was found to be 3 percent and the arithmetic average roughness (Ra) was found to be 42 nm. A thin-film solar cell was formed on this surface electrode, in the same way as in Example 1, and measurement was made of its characteristics. As a result, the photovoltaic conversion efficiency was found to be 7.8 percent.

### Comparative Example 5

A surface electrode was prepared in the same way as in Example 1 except setting the temperature of the soda lime silicate glass substrate in depositing the ITiO film at 200° C. It was found that the sheet resistance was 8.1Ω/□, the haze ratio was 3 percent and the arithmetic average roughness (Ra) was 36 nm. A thin-film solar cell was formed on this surface electrode, in the same way as in Example 1, and measurement was made of its characteristics. As a result, the photovoltaic conversion efficiency was found to be 7.5 percent.

### Comparative Example 6

A surface electrode was prepared in the same way as in Example 1 except setting the temperature of the soda lime silicate glass substrate in depositing the ITiO film at 300° C. The characteristics of the surface electrode are indicated in Table 2. As a result, it was found that the sheet resistance was 8.2Ω/□, the haze ratio was 2 percent and the arithmetic average roughness (Ra) was 37 nm. A thin-film solar cell was formed on this surface electrode, in the same way as in Example 1, and measurement was made of its characteristics. As a result, the photovoltaic conversion efficiency was found to be 7.1 percent.

### Comparative Example 7

A surface electrode was prepared in the same way as in Example 1 except setting the temperature of the soda lime silicate glass substrate in depositing the GAZO film at 240° C. As a result, it was found that the sheet resistance was 8.4Ω/□, the haze ratio was 7 percent and the arithmetic average roughness (Ra) was 55 nm. A thin-film solar cell was formed on this surface electrode, in the same way as in Example 1, and measurement was made of its characteristics. As a result, the photovoltaic conversion efficiency was found to be 7.2 percent.

### Comparative Example 8

A surface electrode was prepared in the same way as in Example 1 except setting the temperature of the soda lime silicate glass substrate in depositing the GAZO film at 350° C. As a result, it was found that the sheet resistance was 7.9Ω/□, the haze ratio was 8 percent and the arithmetic average roughness (Ra) was 53 nm. A thin-film solar cell was formed on this surface electrode, in the same way as in Example 1, and measurement was made of its characteristics. As a result, the photovoltaic conversion efficiency was found to be 7.7 percent.

### Comparative Example 9

A surface electrode was prepared in the same way as in Example 1 except setting the temperature of the soda lime silicate glass substrate in depositing the GAZO film at 330° C. As a result, it was found that the sheet resistance was 9.2Ω/□, the haze ratio was 9 percent and the arithmetic average roughness (Ra) was 54 nm. A thin-film solar cell was formed on this surface electrode, in the same way as in Example 1, and measurement was made of its characteristics. As a result, the photovoltaic conversion efficiency was found to be 7.8 percent.

### Comparative Example 10

A surface electrode was prepared in the same way as in Example 1 except using the ITiTO film of Example 10 as the underlying film 21 and setting the temperature of the soda lime silicate glass substrate in depositing the GAZO film at 330° C., and measurements were made of its characteristics. As a result, it was found that the sheet resistance was 9.0Ω/□, the haze ratio was 10 percent and the arithmetic average roughness (Ra) was 56 nm. A thin-film solar cell was formed on this surface electrode, in the same way as in Example 1, and measurement was made of its characteristics. As a result, the photovoltaic conversion efficiency was found to be 7.9 percent.

### Comparative Example 11

A surface electrode was prepared in the same way as in Example 1 except using the ITGO film of Example 16 as the underlying film 21 and setting the temperature of the soda lime silicate glass substrate in depositing the GAZO film at 330° C., and measurements were made of its characteristics. As a result, it was found that the sheet resistance was 8.9Ω/□, the haze ratio was 9 percent and the arithmetic average roughness (Ra) was 54 nm. A thin-film solar cell was formed on this surface electrode, in the same way as in Example 1, and measurement was made of its characteristics. As a result, the photovoltaic conversion efficiency was found to be 7.9 percent.

TABLE 1

| | film-forming conditions | | | film-forming conditions for | | |
|---|---|---|---|---|---|---|
| | for underlying layer | | | a film with uneven surface | | |
| | | sub- | | | sub- | |
| | | strate | film | | strate | |
| | | temper- | thick- | | temper- | film |
| | material | ature | ness | material | ature | thickness |
| | type | (° C.) | (nm) | type | (° C.) | (nm) |
| Ex. 1 | ITiO | 25 | 200 | GAZO | 300 | 600 |
| Ex. 2 | ITiO | 50 | 200 | GAZO | 300 | 600 |
| Ex. 3 | ITiO | 25 | 200 | GAZO | 250 | 600 |
| Ex. 4 | ITiO | 25 | 300 | GAZO | 300 | 600 |
| Ex. 5 | ITiO | 25 | 400 | GAZO | 300 | 600 |
| Ex. 6 | ITiO | 25 | 500 | GAZO | 300 | 600 |
| Ex. 7 | ITiO | 25 | 200 | GAZO | 300 | 800 |
| Ex. 8 | ITiO | 25 | 200 | GAZO | 300 | 1600 |
| Ex. 9 | ITiO | 25 | 200 | GAZO | 300 | 2000 |
| Ex. 10 | ITiTO | 25 | 200 | GAZO | 300 | 600 |
| Ex. 11 | ITiTO | 25 | 300 | GAZO | 300 | 600 |
| Ex. 12 | ITiTO | 25 | 400 | GAZO | 300 | 600 |
| Ex. 13 | ITiTO | 25 | 400 | GAZO | 300 | 800 |
| Ex. 14 | ITiTO | 25 | 400 | GAZO | 300 | 1600 |
| Ex. 15 | ITiTO | 25 | 400 | GAZO | 300 | 2000 |
| Ex. 16 | ITGO | 25 | 200 | GAZO | 300 | 600 |
| Ex. 17 | ITGO | 25 | 300 | GAZO | 300 | 600 |
| Ex. 18 | ITGO | 25 | 400 | GAZO | 300 | 600 |
| Ex. 19 | ITGO | 25 | 200 | GAZO | 250 | 600 |
| Ex. 20 | ITGO | 25 | 200 | GAZO | 300 | 2000 |
| Comp. Ex. 1 | ITiO | 70 | 200 | GAZO | 300 | 600 |
| Comp. Ex. 2 | ITiO | 100 | 200 | GAZO | 300 | 600 |
| Comp. Ex. 3 | ITiO | 120 | 200 | GAZO | 300 | 600 |
| Comp. Ex. 4 | ITiO | 150 | 200 | GAZO | 300 | 600 |
| Comp. Ex. 5 | ITiO | 200 | 200 | GAZO | 300 | 600 |
| Comp. Ex. 6 | ITiO | 300 | 200 | GAZO | 300 | 600 |
| Comp. Ex. 7 | ITiO | 25 | 200 | GAZO | 240 | 600 |
| Comp. Ex. 8 | ITiO | 25 | 200 | GAZO | 350 | 600 |
| Comp. Ex. 9 | ITiO | 25 | 200 | GAZO | 330 | 600 |
| Comp. Ex. 10 | ITiTO | 25 | 200 | GAZO | 330 | 600 |
| Comp. Ex. 11 | ITGO | 25 | 200 | GAZO | 330 | 600 |

TABLE 2

| | surface electrode characteristics | | | cell characteristics |
|---|---|---|---|---|
| | | | arithmetic | photovoltaic |
| | sheet | haze | average | conversion |
| | resistance | ratio | roughness | efficiency |
| | (Ω/□) | (%) | ( nm) | (%) |
| Ex. 1 | 9.1 | 15 | 63 | 8.4 |
| Ex. 2 | 8.5 | 14 | 60 | 8.2 |
| Ex. 3 | 8.3 | 13 | 61 | 8.3 |
| Ex. 4 | 8.1 | 16 | 64 | 8.5 |
| Ex. 5 | 7.9 | 15 | 64 | 8.4 |
| Ex. 6 | 7.8 | 16 | 65 | 8.4 |
| Ex. 7 | 8.9 | 16 | 65 | 8.5 |
| Ex. 8 | 8.8 | 22 | 66 | 8.5 |
| Ex. 9 | 8.6 | 32 | 68 | 8.4 |
| Ex. 10 | 8.9 | 17 | 66 | 8.5 |
| Ex. 10 | 8.7 | 19 | 67 | 8.5 |
| Ex. 12 | 8.5 | 19 | 67 | 8.4 |
| Ex. 13 | 8.3 | 20 | 70 | 8.5 |
| Ex. 14 | 8.2 | 31 | 72 | 8.6 |
| Ex. 15 | 8.0 | 34 | 72 | 8.3 |
| Ex. 16 | 8.8 | 18 | 67 | 8.6 |
| Ex. 17 | 8.2 | 18 | 67 | 8.7 |
| Ex. 18 | 7.8 | 19 | 68 | 8.8 |
| Ex. 19 | 9.0 | 14 | 62 | 8.2 |
| Ex. 20 | 7.7 | 42 | 73 | 8.8 |
| Comp. Ex. 1 | 8.3 | 9 | 52 | 7.8 |
| Comp. Ex. 2 | 8.2 | 7 | 50 | 7.7 |
| Comp. Ex. 3 | 8.3 | 7 | 43 | 7.9 |
| Comp. Ex. 4 | 8.1 | 3 | 42 | 7.8 |
| Comp. Ex. 5 | 8.1 | 3 | 36 | 7.5 |
| Comp. Ex. 6 | 8.2 | 2 | 37 | 7.1 |
| Comp. Ex. 7 | 8.4 | 7 | 55 | 7.2 |
| Camp. Ex. 8 | 7.9 | 8 | 53 | 7.7 |
| Comp. Ex. 9 | 9.2 | 9 | 54 | 7.8 |
| Comp. Ex. 10 | 9.0 | 10 | 56 | 7.9 |
| Comp. Ex. 11 | 8.9 | 9 | 54 | 7.9 |

It may be seen from the results shown in Tables 1 and 2 that, in Comparative Examples 1 to 6 in which the substrate temperature in depositing the underlying film 21 exceeds 50° C., the haze ratio is less than 10 percent, since the amorphousness of the underlying layer 21 is deteriorated. The photovoltaic conversion efficiency is less than 8.0 percent. In Comparative Example 7, in which the substrate temperature in depositing the film with an uneven surface 22 is lower than 250° C., crystal growth of the GAZO film is retarded. The haze ratio thus is deteriorated, with the photovoltaic conversion rate being lower than 8.0 percent. In Comparative Examples 8 to 11, in which the substrate temperature in depositing the film with an uneven surface 22 exceeds 300° C., the underlying film 21 is deteriorated in amorphousness. Hence, the c-axis orientation of the zinc oxide film is strongly in evidence, with the surface becoming flatter. The haze ratio is worsened, with the photovoltaic conversion rate being lower than 8.0 percent.

On the other hand, with the Examples 1 to 20, in which the substrate temperature in depositing the underlying film 21 is set at ambient to 50° C. and in which the temperature in depositing the film with an uneven surface 22 is set at 250° C. to 300° C., the haze ratio exceeds 10 percent, with the photovoltaic conversion efficiency exceeding 8.0, thus allowing producing an optimum uneven surface.

It should be understood by those skilled in the art that various modifications, combinations and alterations may occur depending on design requirements and other factors insofar as they are within the scope of the appended claims or the equivalents thereof.

1. A transparent electrically conductive substrate on which a surface electrode is formed; said transparent electrically conductive substrate comprising:
an indium oxide based amorphous electrically conductive transparent film and a zinc oxide based crystalline transparent electrically conductive film, sequentially deposited on the transparent substrate to form an uneven surface structure of the surface electrode.

2. The transparent electrically conductive substrate on which a surface electrode is formed, according to claim 1, wherein,
the amorphous electrically conductive transparent film is composed of indium oxide doped with at least one selected from the group consisting of Ti, Sn and Ga.

3. The transparent electrically conductive substrate on which a surface electrode is formed, according to claim 1, wherein,
the crystalline transparent electrically conductive film is formed of zinc oxide doped with at least one selected from the group consisting of Al, Ga, B, In, F, Si, Ge, Ti, Zr and Hf.

4. The transparent electrically conductive substrate on which a surface electrode is formed, according to claim 1, wherein,
the film thickness of the amorphous transparent electrically conductive film is 200 to 500 nm.

5. The transparent electrically conductive substrate on which a surface electrode is formed, according to claim 1, wherein,
the film thickness of said crystalline transparent electrically conductive film is 600 to 2000 nm.

6. A method for manufacturing a transparent electrically conductive substrate on which a surface electrode is formed, comprising:
sequentially layering an indium oxide based amorphous electrically conductive film and a zinc oxide based crystalline transparent electrically conductive film on a light-transmitting substrate to form an uneven surface structure of the surface electrode.

7. The method for manufacturing a transparent electrically conductive substrate on which a surface electrode is formed, according to claim 6, wherein
the temperature of said light-transmitting substrate is kept at ambient to 50° C. and, wherein,
said amorphous transparent electrically conductive film is formed by a sputtering method.

8. The method for manufacturing a transparent electrically conductive substrate on which a surface electrode is formed, according to claim 6, wherein
the temperature of said light-transmitting substrate is kept at ambient to 250° C. to 300° C. and, wherein,
said crystalline transparent electrically conductive film is formed by a sputtering method.

9. A thin-film solar cell in which a surface electrode, a semiconductor layer with a photovoltaic conversion effect and a backside electrode are sequentially formed on a light-transmitting substrate; wherein
said surface electrode is formed on said light-transmitting substrate and made up of an indium oxide based amorphous transparent electrically conductive film and a zinc oxide based crystalline transparent electrically conductive film stacked together to present an crests and troughs.

10. A method for manufacturing a thin-film solar cell in which a surface electrode, a semiconductor layer with a photovoltaic conversion effect and a backside electrode are sequentially formed on a light-transmitting substrate; said method comprising
sequentially depositing, on said light-transmitting substrate, an indium oxide based amorphous transparent electrically conductive film and a zinc oxide based crystalline transparent electrically conductive film to form an uneven surface on said surface electrode.

11. The transparent electrically conductive substrate on which a surface electrode is formed, according to claim 2, wherein,
the crystalline transparent electrically conductive film is formed of zinc oxide doped with at least one selected from the group consisting of Al, Ga, B, In, F, Si, Ge, Ti, Zr and Hf.

12. The transparent electrically conductive substrate on which a surface electrode is formed, according to claim 2, wherein,
the film thickness of the amorphous transparent electrically conductive film is 200 to 500 nm.

13. The transparent electrically conductive substrate on which a surface electrode is formed, according to claim 3, wherein,
the film thickness of the amorphous transparent electrically conductive film is 200 to 500 nm.

14. The transparent electrically conductive substrate on which a surface electrode is formed, according to claim 2, wherein,
the film thickness of said crystalline transparent electrically conductive film is 600 to 2000 nm.

15. The transparent electrically conductive substrate on which a surface electrode is formed, according to claim 3, wherein,
the film thickness of said crystalline transparent electrically conductive film is 600 to 2000 nm.

16. The transparent electrically conductive substrate on which a surface electrode is formed, according to claim 4, wherein,
the film thickness of said crystalline transparent electrically conductive film is 600 to 2000 nm.

17. The method for manufacturing a transparent electrically conductive substrate on which a surface electrode is formed, according to claim 7, wherein
the temperature of said light-transmitting substrate is kept at ambient to 250° C. to 300° C. and, wherein,
said crystalline transparent electrically conductive film is formed by a sputtering method.
